(19) United States
(12) Patent Application Publication
(10) Pub. No.: US 2009/0284915 A1
(43) Pub. Date: Nov. 19, 2009

(54) COMPUTER ENCLOSURE WITH DETACHABLE TOP COVER

(75) Inventors: LUNG-SHENG TSAI, Tu-Cheng (TW); YI-LUNG CHOU, Tu-Cheng (TW); LI-PING CHEN, Tu-Cheng (TW); CHIA-KANG WU, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/180,248

(22) Filed: Jul. 25, 2008

(30) Foreign Application Priority Data
May 16, 2008 (CN) 200820300754.9

(51) Int. Cl. H05K 5/00; A47B 81/00

(52) U.S. Cl. 361/679.58; 312/223.2

(57) ABSTRACT

A computer enclosure includes a chassis (10), a top cover (30) mounted to the chassis and a lever (90). The chassis includes a sidewall (13). A rim (131) formed on a top portion of the sidewall. The top cover includes a top panel (31) with an edge (32) formed thereon. The lever is pivotably attached to the edge of the top cover. The lever includes a propelling portion (93) and a handle (91) formed on opposite end of the propelling portion. The lever is capable of being rotated, engage the rim of the sidewall, and release the top cover from the chassis.

### BACKGROUND

1. Technical Field

The present invention relates to a computer enclosure, particularly to a computer enclosure in which a top cover thereof is conveniently detached by upward movement of a lever.

2. Description of Related Art

Generally, there are frequent occasions when a user must replace or repair hardware components disposed within a computer. To facilitate maintenance, computer chassis typically include a removable cover.

However, in such conventional computers, the removable cover is attached to the chassis by fasteners, and a tool is needed to remove or install the cover. Furthermore, because the cover and the chassis have completely separate structures from each other, it is difficult to correctly align the cover with the chassis during assembly.

Therefore, a need exists for a computer having a chassis with an improved detachable cover for allowing a user to easily replace and/or repair hardware components accommodated in the chassis.

### BRIEF DESCRIPTION OF THE DRAWINGS

FIG. 1 is an isometric, exploded view of a chassis and a top cover of a computer enclosure of an exemplary embodiment of the present invention;

FIG. 2 is a partial sectional view of a sidewall of the chassis of a computer enclosure of an exemplary embodiment of the present invention;

FIG. 3 is an isometric view of the top cover of the exemplary embodiment of the present invention;

FIG. 4 is an assembled view of FIG. 1;

FIG. 5 is similar to FIG. 4, but showing from another aspect; and

FIG. 6 is similar to FIG. 4, but showing a detaching state of the computer enclosure.

### DETAILED DESCRIPTION

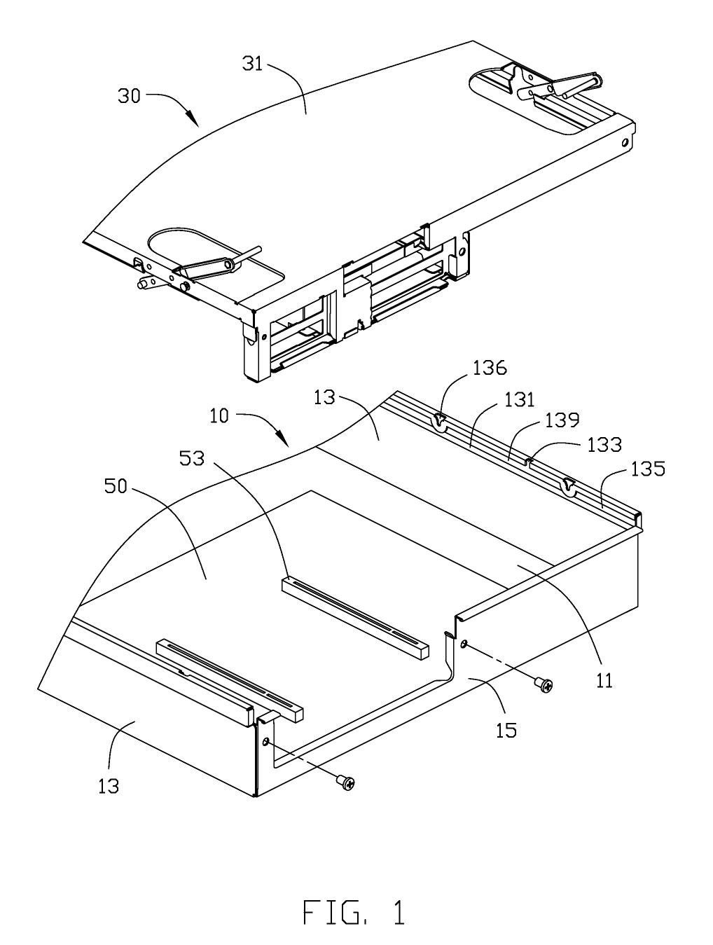

Referring to FIG. 1, a computer enclosure includes a chassis 10 and a top cover 30.

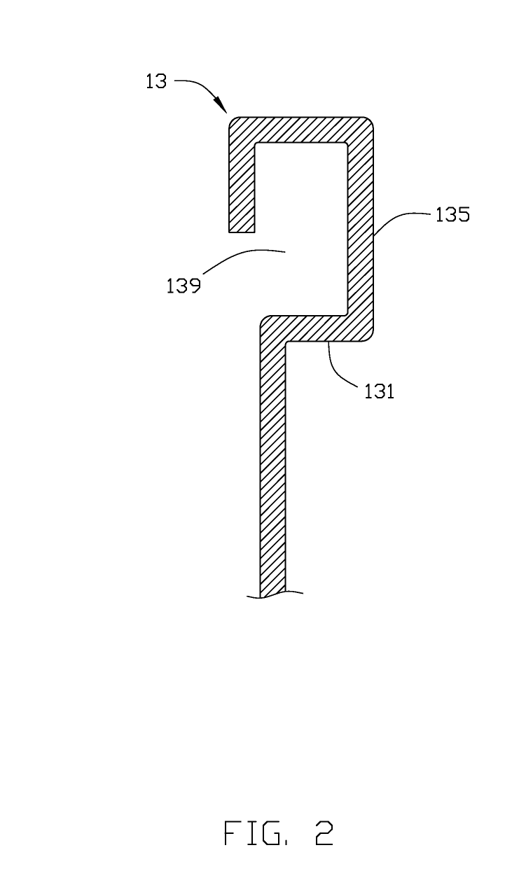

The chassis 10 includes a bottom panel 11, a pair of parallel sidewalls 13 extending from opposite sides of the bottom panel 11 and a front panel 15. Referring also to FIG. 2, A rim 131 is horizontally formed on a top portion of each sidewall 13. A generally upside-down U-shaped receiving flange 135 is formed on a distal end of the rim 131. A receiving space 139 is cooperatively defined by the rim 131 and the receiving flange 135. Each receiving flange 135 defines two T-shaped recesses 136 at a top portion and an inner portion of the receiving flange 135. A cutout 133 is defined in one of the flanges 135 of the chassis 10. A motherboard 50 is disposed in the chassis 10. The motherboard 50 has at least one slot 53.

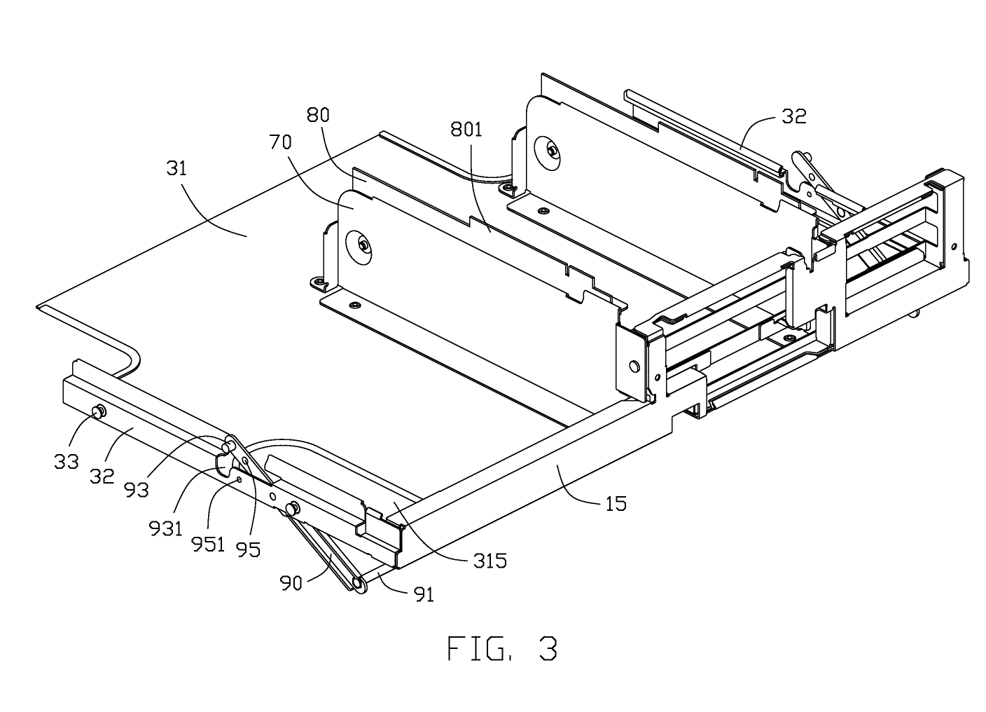

Referring also to FIG. 3, the top cover 30 includes a top panel 31 and a pair of external edges 32 perpendicularly extending from opposite sides of the top panel 31. A lever 90 is pivotable to each external edge 32 of the top cover 30. A handle 91 and a propelling portion 93 are respectively formed on opposite ends of the lever 90. A round lump 95 is formed on an outer surface of the lever 90. An opening 315 is defined in the top panel 31 adjacent to each external edge 32, so that the lever 90 is accessible through the top cover 31 from an outer side thereof. Each external edge 32 has two T-shaped locking bulges 33 at an outer surface thereof for engaging with the corresponding recesses 136 of the chassis. A cutout 931 is defined in each external edge 32 for receiving the propelling portion 93. A hole or recess 951 is defined in an inner surface of the external edge 32 for engaging with the lump 95 of the lever 90, thereby the lever 90 held at an inner surface of the external edge 32. At least one expansion card 80 mounted in a bracket 70 is arranged at an inner surface of the top panel 31. Each expansion card 80 has a connector 801 communicating with the motherboard 50 through the slot 53.

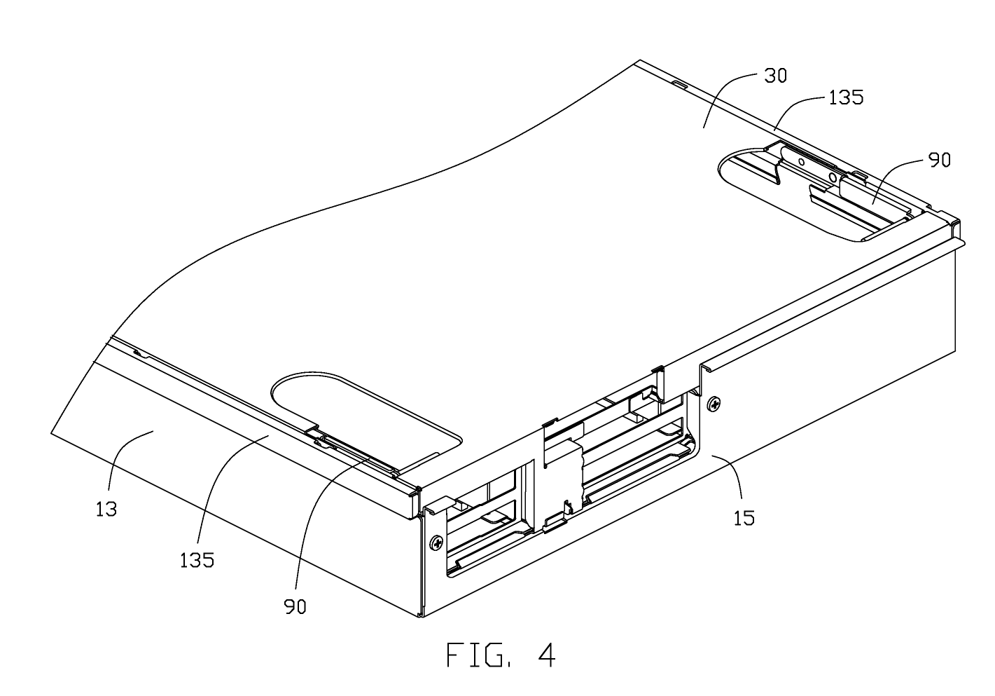

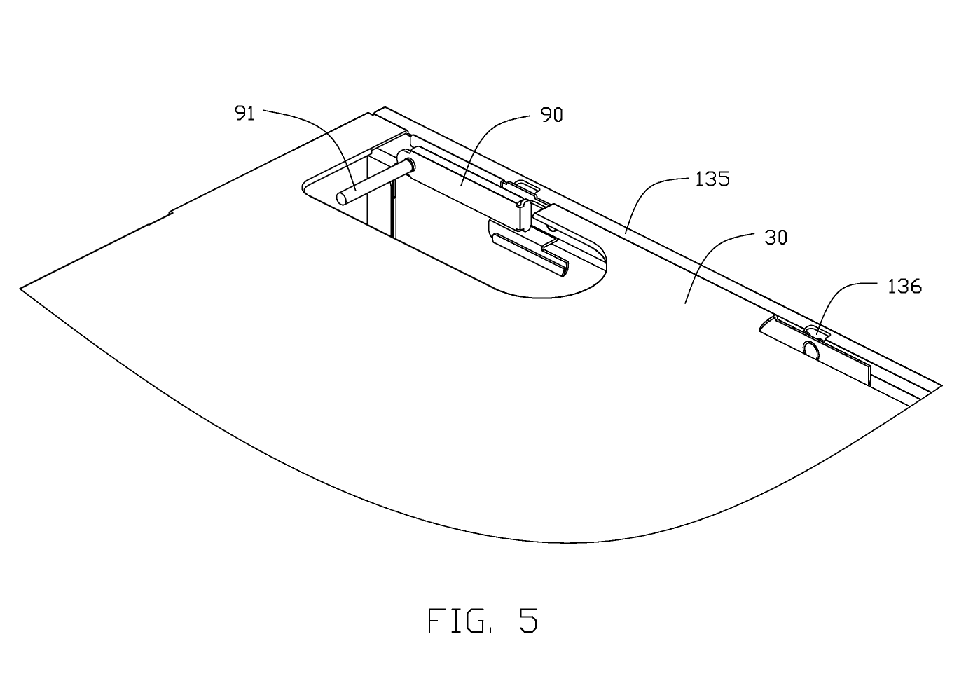

Referring through FIG. 4 to FIG. 6, assembled views of the top cover 30 and the chassis 10 are shown. When assembling the top cover 30 to the chassis 10, the levers 90 are rotated to an open position where the handle 91 with each lever 90 is positioned above the top panel 31. The propelling portion 93 of one lever 90 is first positioned into the receiving space 139 of one sidewall 13, and the propelling portion 93 of other lever 90 is positioned into the receiving space 139 through the cutout 133. Then the top cover 30 is moved down towards the chassis 10 with the locking bulges 33 engaging with the flanges 135 in the correspondingly recess 136 thereof. Then the levers 90 are urged to rotate to an original position where the lever 90 is attached to the inner surface of the external edge 32. The connector 801 of the expansion card 80 is inserted into the corresponding slot 53 of the motherboard 50, so that the expansion card 80 could communicate with the motherboard 50. The top cover 30 is assembled to the chassis 10.

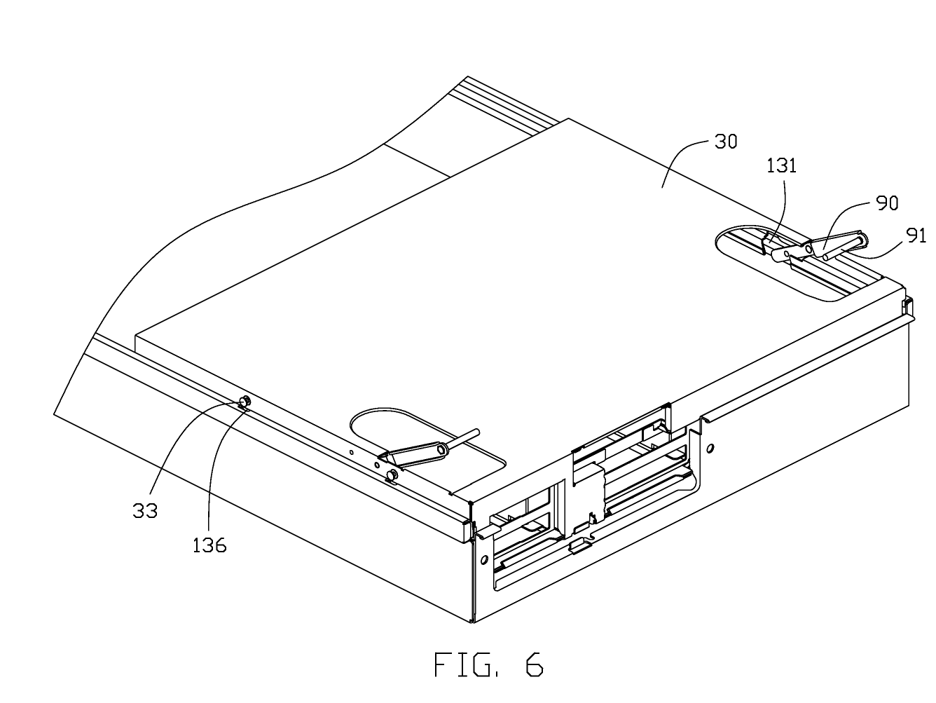

Referring in particular to FIG. 6, a detached view of the top cover 30 and the chassis 10 is shown. When detaching the top cover 30 from the chassis 10, the handles 91 of the levers 90 are moved upward, and the propelling portions 93 of the levers 90 urge the corresponding rims 131 to raise the top cover 10. The locking bulges 33 are detached from the flanges 135 of the chassis 10, and the at least one expansion card 80 is detached from the motherboard 50. The top cover 30 is then detached from the chassis 10.

The computer enclosure of the present invention has following advantages: first, little force is needed to manipulate the lever 90; second, the expansion card 80 on the top cover 30 can be readily detached from the motherboard 50 with the detachment of the top cover 30 from the chassis 10 by lifting up the lever 90.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A computer enclosure, comprising:
a chassis comprising a sidewall and a rim formed on a top portion of the sidewall;
a top cover mounted to the chassis, the top cover comprising a top panel with an edge formed thereon; and
a lever pivotably attached to the edge of the top cover, the lever comprising a propelling portion extending from a first end and a handle extending from a second end,
wherein the lever is capable of being rotated, cause the propelling portion releasably engage the rim, and release the top cover from the chassis.

2. The computer enclosure as claimed in claim 1, wherein a lump is formed on the lever, and a recess and hole is defined in an inner surface of the edge to engage with the lump, so that the lever is capable of being hold inside the edge.

3. The computer enclosure as claimed in claim 1, wherein the chassis further comprises a flange on a top portion of the sidewall, and the edge of top cover is in contact with the flange.

4. The computer enclosure as claimed in claim 3, wherein the flange defines at least one recess, the top cover comprises at least one T-shaped locking bulge, and the recess receives the locking bulge therein.

5. The computer enclosure as claimed in claim 1, wherein a cutout is defined in the edge of the top cover and the cutout is capable of receiving the propelling portion; the lever is attached to an inner surface of the edge.

6. The computer enclosure as claimed in claim 1, wherein an opening is defined in the top panel adjacent to the lever, and the lever is accessible through the top cover from an outer side thereof.

7. A computer comprising:
a chassis;
a motherboard positioned within the chassis, the motherboard comprising a slot;
a top cover mounted to the chassis;
an expansion card mounted to an inner side of the top cover, the expansion card engaged with the slot of the motherboard; and
a lever pivotably attached to the top cover,
wherein the lever is capable of movably rotating between a first position and a second position; the first position is where the lever is positioned paralleled to the top cover; the second position is where the lever is positioned angle to the top cover.

8. The computer as claimed in claim 7, wherein the chassis comprises a sidewall, and a flange is formed on a top portion of the sidewall.

9. The computer as claimed in claim 8, wherein the flange defines at least one recess, and at least one T-shaped locking bulge protrudes from an outer surface of the edge, and the recess receives the locking bulge therein.

10. The computer as claimed in claim 7, wherein the lever comprises a propelling portion and a handle formed on opposite end of the propelling portion, and the top cover is capable of being detached from the chassis when urged by the propelling portion.

11. The computer as claimed in claim 7, wherein a lump is formed on the lever, and a recess or hole is defined in an inner surface of the top cover to engage with the lump in the first position.

12. The computer as claimed in claim 7, wherein an opening is defined in the top panel adjacent to the lever, thereby the lever is accessible through the top cover from an outer side thereof.

13. A computer enclosure, comprising:
a chassis comprising two sidewalls, and the chassis capable of receiving computer component therein;
a top cover sandwiched between two top portions of two sidewalls; and
a lever pivotably attached to the top cover, the lever forming a propelling portion at a distal end thereof,
wherein the propelling portion is capable of urging the top cover to disengage from the sidewall by rotating the lever from a first position to a second position.

14. The computer enclosure as claimed in claim 13, wherein a lump is formed on the lever, and a recess or hole is defined in the top cover to engage with the lump when the lever is in the first position.

15. The computer enclosure as claimed in claim 13, wherein a flange is formed on the top portion of at least one of the two sidewalls; the flange defines at least one recess, and at least one T-shaped locking bulge protrudes from an external edge of the top cover, and the recess receives the locking bulge therein.

16. The computer enclosure as claimed in claim 13, wherein a cutout is defined in the top cover, the cutout is capable of receiving the propelling portion, thereby the lever is connected to an inner surface of the top cover.

17. The computer enclosure as claimed in claim 13, wherein a handle is formed on the lever, and a second opening is defined in the top cover adjacent to the lever, thereby the handle is accessible through the top cover from an outer side thereof.
